(19) United States
(12) Patent Application Publication
(10) Pub. No.: US 2004/0097087 A1
(43) Pub. Date: May 20, 2004

(54) Chamber structure in inductive coupling plasma etching apparatus

(76) Inventor: Dong-Bock Lee, Suwon-City (KR)

Correspondence Address: VOLENTINE FRANCOS, P.L.L.C., Suite 150, 12200 Sunrise Valley Drive, Reston, VA, 20191, US

(21) Appl. No.: 10/697,032

(22) Filed: Oct. 31, 2003

(30) Foreign Application Priority Data
Nov. 18, 2002 (KR) 2002-71518

(51) Int. Cl. C23F 1/00; H01L 21/306; H01L 21/302; H01L 21/461

(52) U.S. Cl. 438/690

(57) ABSTRACT

A chamber structure of an inductive coupling plasma etching apparatus includes an etch chamber for an etching process; a plasma chamber for generating plasma; and a segregation wall part having a portion within the etch chamber made of ceramic material and a portion within the plasma chamber made of quartz material, whereby the segregation wall part separates the etch chamber from the plasma chamber.

### BACKGROUND OF THE INVENTION

1. Field of the Invention

The present invention relates to a chamber structure of an inductive coupling plasma etching apparatus.

A claim of priority is made to Korean Patent Application No. 2002-71518, filed Nov. 18, 2002, the contents of which are incorporated herein by reference.

2. Description of the Related Art

In general, examples of plasma sources used in a plasma etching apparatus include a high frequency capacitive coupling plasma source, a microwave ECR plasma source, and a high frequency inductive coupling plasma source, etc. These plasma sources individually have different characteristics. Among these three plasma sources, plasma process apparatuses including high frequency inductive coupling plasma (ICP) sources have been given consideration recently.

According to conventional technology, an inductive coupling plasma etching apparatus has a structure wherein a plasma chamber is separated from an etch chamber by a segregation wall part made of quartz material.

In an etch chamber of such a conventional apparatus where a plasma etching process is performed, etching residuals such as a polymer remain after execution of the process, in such a state that the polymer adheres the quartz material ceiling of the etch chamber. Polymer is repeatedly accumulated under an unstabilized state on the quartz material ceiling of the chamber during consecutive etching processes. This polymer may become detached from the quartz material ceiling owing to internal/external causes, and may fall onto a wafer. Polymer that falls onto a wafer may cause structural defects in wiring patterns, thus resulting in defectively manufactured semiconductor devices.

Meanwhile, in the case that the segregation wall part is made of a material that promotes stabilized deposition of polymer generated during the etching process, there is a further different problem that formation of plasma in a plasma chamber positioned on an upper part of the etch chamber is difficult.

### SUMMARY OF THE INVENTION

Therefore, an object of the present invention is to provide a chamber structure of an inductive coupling plasma etching apparatus that prevents polymer generated during an etching process in an etch chamber from being unstably accumulated on the etch chamber, and that enables plasma to be easily generated in a plasma chamber, thereby reducing the occurrence of defective semiconductor devices and enhancing production efficiency.

To achieve these and other objects, the chamber structure of an inductive coupling plasma etching apparatus in accordance with an aspect of the present invention includes an etch chamber in which an etching process is carried out; a plasma chamber in which plasma is generated; and a segregation wall part having a portion made of ceramic material opposite to the etch chamber, and having a portion made of quartz material opposite to the plasma chamber, the segregation wall part separating the etch chamber from the plasma chamber.

The chamber structure of an inductive coupling plasma etching apparatus in accordance with another aspect of the present invention is equipped with a chamber of cylindrical shape divided by one segregation wall part into a first chamber wherein an etching process is performed and a second chamber in which plasma is generated. The chamber structure includes the segregation wall part having a portion made of ceramic material that is a ceiling of the first chamber, and having a portion made of quartz material that is a bottom of the second chamber.

The chamber structure of an inductive coupling plasma etching apparatus in accordance with a still another aspect of the present invention is equipped with a chamber of cylindrical shape divided by one segregation wall part into an upper chamber and a lower chamber. The chamber structure includes the segregation wall part having a portion made of ceramic material that is a ceiling wall of the lower chamber, and having a portion made of quartz material that is a bottom wall of the upper chamber. Plasma is generated in the upper chamber and an etching process is performed in the lower chamber.

### BRIEF DESCRIPTION OF THE DRAWINGS

The above and other objects and features of the present invention will become apparent from the following description of the preferred embodiments thereof made in conjunction with the accompanying drawing, in which:

FIG. 1 is a drawing showing a chamber structure of an inductive coupling plasma etching apparatus in accordance with the present invention.

### DETAILED DESCRIPTION OF THE PREFERRED EMBODIMENTS

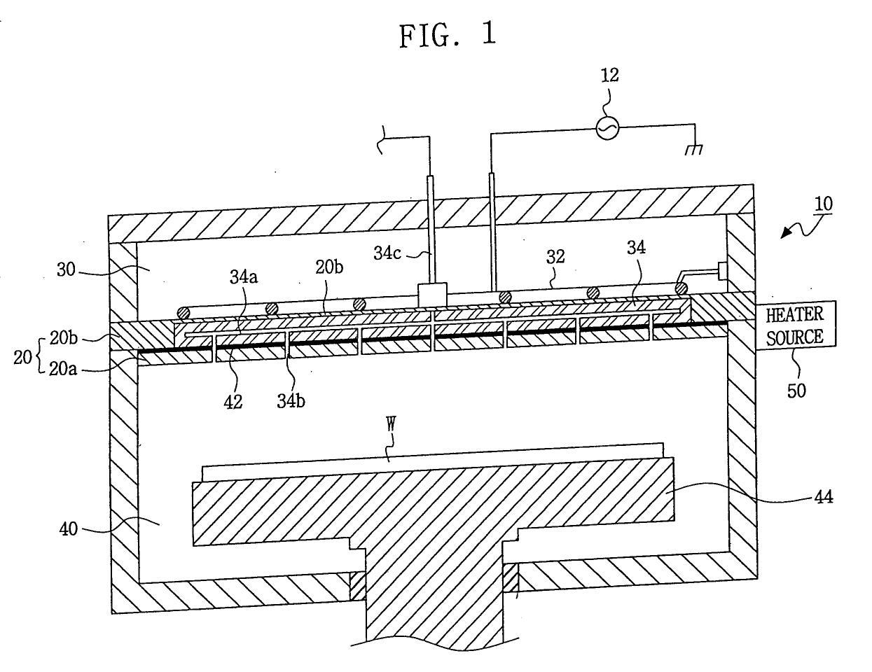

FIG. 1 illustrates a chamber structure of an inductive coupling plasma etching apparatus in accordance with an exemplary embodiment of the present invention. Referring to FIG. 1, the chamber structure has a chamber 10 of cylindrical shape made of conductive material. The chamber 10 is divided into an upper chamber 30 and a lower chamber 40 by one segregation wall part 20.

The segregation wall part 20 is a ceiling wall of the lower chamber 40 where an etching process is performed, and simultaneously is a bottom wall of the upper chamber 30 where plasma is formed.

In the segregation wall part 20, the portion that is the ceiling wall of the lower chamber 40, namely lower face 20a of the segregation wall part, is made of a material like ceramic, and the portion that is the bottom wall of the upper chamber 30, namely upper face 20b of the segregation wall part, is made of a material like quartz.

The ceiling face of the lower chamber 40 made of ceramic material, namely the lower face 20a of the segregation wall part, is disposed face to face with an electrostatic chuck 44 on which a wafer W is mounted. On an upper part of the lower face 20a of the segregation wall part, a heater 42 is disposed, and a lead line (not shown) connected to the heater 42 is coupled with a heater source 50 through the interior of a sidewall of the chamber 10.

On the bottom face of the upper chamber 30, namely the upper face 20b of the segregation wall part which is made of quartz material, a high frequency antenna 32 is installed. The high frequency antenna 32 is arranged as a plane-type coil antenna, and a center end part of the high frequency antenna 32 is connected to a high frequency power source 12 through a matcher (not shown) etc.

In the interior of the upper face 20b of the segregation wall part, a shower housing body 34 for use as a process gas supply is installed. In the interior of the shower housing body 34, a gas flow path 34a extending horizontally is formed. The gas flow path 34a also extends downward, to thus form numerous gas exhaust holes 34b which are respectively opened, piercing through the lower face 20a of the segregation wall part provided with the heater 42 of sheet shape. On a center of the upper face 20b of the segregation wall part, a gas supply line 34c is equipped in connection with the gas flow path 34a.

Operations of the inductive coupling plasma etching apparatus will be described as follows.

The wafer W is stably mounted on the electrostatic chuck 44 of the lower chamber 40 which is used as a process room. Then, the process gas is supplied from a gas supply source (not shown) through the gas supply line 34c, and is then exhausted into the chamber 10 through the gas exhaust holes 34b of the shower housing body 34. At the same time, the process gas is discharged to the outside through an exhaust pipe of an exhaust instrument (not shown), to thus form the interior of the chamber 10 as a uniform pressure atmosphere by the supplied process gas.

Next, high frequency power from the high frequency power source 12 is applied to the high frequency antenna 32, to thus form an inductive electric field within the chamber 10. Subsequently, the process gas becomes plasma by the inductive electric field within the chamber 10, to then generate inductive coupling plasma of a high density. Ions of the generated plasma are effectively led to the wafer W by high frequency power (not shown) applied to the electrostatic chuck 44, so as to perform a uniform etching process on the wafer W.

This chamber structure that uses high density inductive coupling plasma has the segregation wall part 20 which is constructed of an upper face 20b made of a material like quartz and a lower face 20a made of a material like ceramic. That is, the segregation wall part 20 is made of two kinds of material. The upper face 20b of the segregation wall part is made of a material like quartz, so that plasma may be easily generated in the upper chamber 30. Also, the lower face 20a of the segregation wall part is made of a material like ceramic, to enable a more stable deposition of polymer generated during the etching process in the lower chamber 40.

Therefore, the apparatus of the present invention can be efficiently utilized by using material appropriate for each of two processes executed in the high density inductive coupling plasma chamber, namely for plasma formation and for etching.

As described, the upper face 20b of the segregation wall part is made of a material like quartz, and the lower face 20a of the segregation wall part is made of a material like ceramic. A prominent characteristic of ceramic material advantageous for use as the lower face 20a in contrast to quartz material that is conventionally used, will be described as follows.

The heat conductivity of a material like ceramic is about 20 times greater than the heat conductivity of a material like quartz, and a surface toughness of a material like ceramic is about 1.4 times higher than a material like quartz. When a material such as ceramic having high surface toughness is used as the ceiling face of a chamber in which an etching process is carried out, polymer can stably adhere onto the tough surface of the material. In addition, when the material of the ceiling face of a chamber in which an etching process is carried out has high heat conductivity, temperature of the chamber can rise more highly. When temperature in the chamber is high, polymer can strongly adhere onto the lower face of the segregation wall part. Consequently, a ceramic material enables a more stable deposition of polymer generated during the etching process than a quartz material.

As described, in the chamber structure of the inductive coupling plasma etching apparatus of the present invention, the ceiling of the chamber where etching processes are carried out is made of a ceramic material, so that polymer may be stably deposited on the interior of the chamber during an etching process. Also, the bottom of the chamber where plasma is generated is formed with quartz material, so that plasma may be easily generated.

That is to say, in one segregation wall part for dividing a cylindrical chamber into two chambers, an upper face of the segregation wall part is made of quartz material so that plasma may be easily generated, and a lower face thereof is made of a ceramic material to enable stabilized deposition of polymer. Thus, one segregation wall part is formed of two materials, quartz material and ceramic material.

With such a chamber structure of an inductive coupling plasma etching apparatus as in the present invention, one segregation wall part for dividing the chamber is arranged so that a portion of the segregation wall part within an etch chamber is made of ceramic material and a portion of the segregation wall part within a plasma chamber is made of quartz material. Thus, polymer generated during the etching process can stably adhere to the portion of the segregation wall part that is made of the ceramic material and located face to face with the etch chamber. Also, plasma can be easily generated in the plasma chamber having a portion of the segregation wall part that is made of quartz material and located face to face with the plasma chamber. Thereby, defects in processed semiconductor devices can be reduced and productivity can be increased.

As described in accordance with the present invention, polymer can stably adhere to the chamber structure of an inductive coupling plasma etching apparatus, and plasma can be easily generated, by using a segregation wall part formed with two materials: a ceramic material and a quartz material. Accordingly, the defect occurrence rate of semiconductor device processing can be lowered while increasing production efficiency.

Finally, although the present invention was described in detail above in connection with the preferred embodiments thereof, the scope of the invention is not so limited. Rather, various changes and modifications of the preferred embodiments, as will become apparent to those of ordinary skill in the art, are seen to be within the true spirit and scope of the invention as defined by the appended claims.

What is claimed is:

1. A chamber structure of an inductive coupling plasma etching apparatus, comprising:
an etch chamber in which an etching process is performed;
a plasma chamber in which plasma is generated; and
a segregation wall part having a portion made of ceramic material opposite to the etch chamber, and having a portion made of quartz material opposite to the plasma chamber, the segregation wall part separating the etch chamber from the plasma chamber.

2. The chamber structure of claim 1, wherein the plasma chamber is in an upper portion of the chamber structure, and the etch chamber is in a lower portion of the chamber structure.

3. The chamber structure of claim 1, which is of cylindrical shape.

4. The chamber structure of claim 1, wherein the portion of the segregation wall part opposite to the etch chamber includes a heater that heats the ceramic material.

5. The chamber structure of claim 1, wherein the segregation wall part includes gas flow paths and gas exhaust holes that supply process gas into the etch chamber.

6. A chamber structure of an inductive coupling plasma etching apparatus, the chamber structure having cylindrical shape and being divided by one segregation wall part into a first chamber wherein an etching process is performed and a second chamber in which plasma is generated,
the segregation wall part having a portion made of ceramic material that is a ceiling of the first chamber, and having a portion made of quartz material that is a bottom of the second chamber.

7. The chamber structure of claim 6, wherein the portion of the segregation wall part that is a ceiling of the first chamber includes a heater.

8. The chamber structure of claim 6, wherein the segregation wall part includes gas flow paths and gas exhaust holes that supply process gas into the first chamber.

9. A chamber structure of an inductive coupling plasma etching apparatus of cylindrical shape divided into an upper chamber and a lower chamber by one segregation wall part,
the segregation wall part having a portion made of ceramic material that is a ceiling wall of the lower chamber, and having a portion made of quartz material that is a bottom wall of the upper chamber.

10. The chamber structure of claim 9, wherein plasma is generated in the upper chamber.

11. The chamber structure of claim 9, wherein an etching process is performed in the lower chamber.

12. The chamber structure of claim 9, wherein the portion of the segregation wall part that is a ceiling wall of the lower chamber includes a heater.

13. The chamber structure of claim 9, wherein the segregation wall part includes gas flow paths and gas exhaust holes that supply process gas into the lower chamber.
